(19) United States
(12) Patent Application Publication
(10) Pub. No.: US 2014/0119703 A1
(43) Pub. Date: May 1, 2014

(54) Printed Circuit Board Comprising Both Conductive Metal and Optical Elements

(71) Applicant: CISCO TECHNOLOGY, INC., San Jose, CA (US)

(72) Inventors: Scott Hinaga, Palo Alto, CA (US); David Senk, San Jose, CA (US); Brice Achkir, San Jose, CA (US)

(73) Assignee: CISCO TECHNOLOGY, INC., San Jose, CA (US)

(21) Appl. No.: 13/661,095

(22) Filed: Oct. 26, 2012

(51) Int. Cl. H05K 3/00; G02B 6/10

(52) U.S. Cl. 385/130; 156/60; 216/20; 156/268

(57) ABSTRACT

A printed circuit board (PCB) may be provided. The PCB may comprise a first electrically conductive layer comprising a first signal layer. Also, the PCB may comprise a second electrically conductive layer comprising a second signal layer or a plane layer associated with the first signal layer. The PCB may further comprise a waveguide layer disposed between the first electrically conductive layer and adjacent the second electrically conductive layer. The waveguide layer may transmit optical signals and function as a dielectric between the first electrically conductive layer and the second electrically conductive layer.

### BACKGROUND

A printed circuit board (PCB) is used to mechanically support and electrically connect electronic components using conductive pathways, tracks, or signal traces etched from copper sheets laminated onto a non-conductive substrate. A PCB populated with electronic components is called a printed circuit assembly (PCA), printed circuit board assembly, or PCB Assembly (PCBA).

### BRIEF DESCRIPTION OF THE DRAWINGS

The accompanying drawings, which are incorporated in and constitute a part of this disclosure, illustrate various embodiments of the present disclosure. In the drawings:

FIGS. 1A through 1D show PCBs;

FIG. 2 shows a representative backplane PCB;

FIG. 3 is a flow chart of a method for providing a PCB;

FIGS. 4A through 4E show a PCB;

FIG. 5 is a flow chart of a method for providing a PCB; and

FIGS. 6A through 6F show a PCB.

### DETAILED DESCRIPTION

### Overview

The disclosure may generally relate to the design and fabrication of a printed circuit board (PCB). More particularly, the disclosure may relate to a method of architecture, designing, and fabricating multilayer printed circuit boards that may contain both conductive metallic circuit elements and optical interconnect elements.

Both the foregoing overview and the following example embodiment are examples and explanatory only, and should not be considered to restrict the disclosure's scope, as described and claimed. Further, features and/or variations may be provided in addition to those set forth herein. For example, embodiments of the disclosure may be directed to various feature combinations and sub-combinations described in the example embodiment.

### Example Embodiments

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

A multilayer printed circuit board conventionally comprises etched metal circuit patterns interleaved between sheets of dielectric material, laminated together into a discrete PCB. The dielectric may comprise an organic resin impregnating a sheet of woven or non-woven fabric of either inorganic or organic material (pre-preg). The presence of the fabric provides structural rigidity to the finished product. In the sub-class of printed circuit boards known as flexible circuits, the dielectric may lack the fabric, thus consisting only of resin, and the finished PCB may be rendered flexible by the lack of fabric reinforcement.

In such a multilayer PCB, the circuit patterns applied to the metal layers comprises etched metal traces (i.e., wires of rectangular or trapezoidal cross-section) that may carry an electrical current or signal from one location on the PCB to another. Layers, whose circuitry predominantly comprise traces, are referred to as signal layers.

A circuit layer may comprise contiguous metal in which small areas are relieved to allow the passage of drilled holes through the layer. Such layers may be used to provide an electrical ground return pathway (electrical reference) for signals within the PCB, or to furnish electrical power to the components mounted on the PCB. Layers of either sort may be referred to as plane layers.

A stacked arrangement (i.e., stackup) of plane and signal layers within the PCB may be important in the design of PCBs intended to operate at high frequencies or signal speeds. Plane and signal layers may be stacked alternately so that the plane layers may serve as electrical reference planes for the adjacent signal layers. Furthermore, plane layers may serve to provide electrical shielding around high-speed traces, thus preventing undesired electromagnetic radiation in the vicinity of the operating PCB, and may further serve to isolate signal layers from each other, thus minimizing undesired electromagnetic interaction (crosstalk) between said layers.

In such high-speed PCBs, the electrical characteristics of the dielectric material; in particular, the Dielectric Constant (Dk) and Dissipation Factor (Df) may be critical as to proper functioning of the circuit. The designer of the circuit may select and specify from a wide choice of commercially-available dielectrics of varying Dk and Df, in order to ensure proper operation of the circuit.

An optical PCB differs from a conventional PCB in that the signals are conveyed through the transmission of photons (light) rather than electrons. The conducting medium is not metallic, but rather an optically transparent material, such as glass or plastic, through which the photonic signals are conveyed.

Optical media may comprise discrete glass or plastic filaments (fiber-optics), or mechanically-formed waveguides that may be laminated within, or attached to the external surface of, a PCB. The waveguides may also be formed by photo-imaging of the desired waveguide pattern upon a sheet of photo-sensitive film, wherein the undesired areas of the film may be developed away, leaving behind the formed waveguides.

In either instance, a key characteristic of the optical media may be transparency (i.e., the ability to transmit light without absorption), refractive index, and stability of these characteristics with respect to changes in temperature. As such optical media are not associated with the flow of electrons. In other words, the Dk and Df of the material may not be critical to the function of the waveguide.

Conversely, in a conventional PCB based on metal circuitry, electrical characteristics (Dk and Df) of the dielectric may be important to circuit function. At the same time, such dielectrics, being partially or principally opaque to light transmission, are wholly unsuitable for use as optical circuit elements, and thus transparency and refractive index of the material have no impact upon circuit function.

Consistent with embodiments of the disclosure, a PCB may be provided in which a material may function simultaneously as a dielectric between metallic signal and trace layers, and also as an optical medium for transmission of photonic signals. Such materials may possess favorable properties for both functions, including, for example, Dk and Df for the dielectric function, and optical transparency, refractive index, and temperature stability for the optical medium function. Consistent with embodiments of the disclosure, a given layer of material may serve both the functions of optical transmission and dielectric between conductive metal PCB layers.

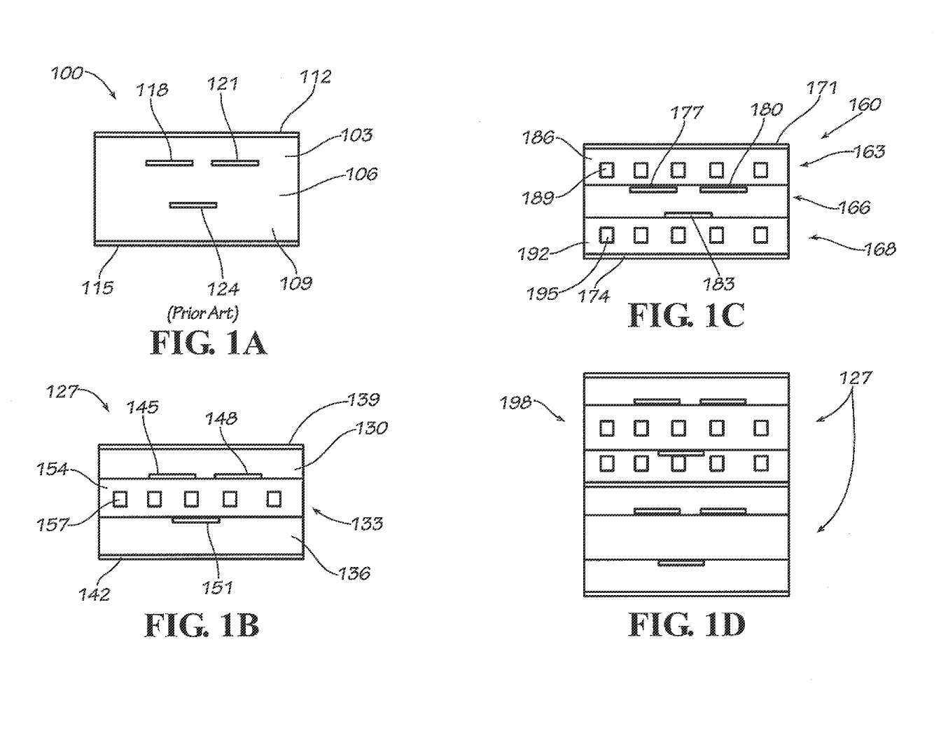

FIG. 1A shows a PCB 127 consistent with embodiments of the disclosure. As shown in FIG. 1B, PCB 127 may comprise a first dielectric layer 130, a waveguide layer 133, and a second dielectric layer 136 between a first plane layer 139 and a second plane layer 142. A first signal layer, which may comprise a first trace 145 and a second trace 148, may be located between first dielectric layer 103 and waveguide layer 133. A second signal layer, which may comprise a third trace 151, may be located between waveguide layer 133 and second dielectric layer 136. Waveguide layer 133 may comprise a cladding 154 encapsulating a plurality of waveguides 157. A material comprising cladding 154 may have a different refractive index than a material comprising any of plurality of waveguides 157. The difference in refractive index may tend to cause light traveling in plurality of waveguides 157 to stay in the waveguides and not dissipate into cladding 154.

Consistent with embodiments of the disclosure, waveguide layer 133 may serve simultaneously as a layer for providing optical waveguides (e.g., plurality of waveguides 157) and as a dielectric between signal layers (e.g., the first signal layer and the second signal layer). For example, waveguide layer 133 may have at least the same dielectric qualities as the prior art dielectric layer (i.e., second dielectric layer 106).

FIG. 1B shows a PCB 160 consistent with embodiments of the disclosure. As shown in FIG. 1B, PCB 160 may comprise a first waveguide layer 163, a dielectric layer 166, and a second waveguide layer 168 between a first plane layer 171 and a second plane layer 174. A first signal layer, which may comprise a first trace 177 and a second trace 180, may be located between first waveguide layer 163 and dielectric layer 166. A second signal layer, which may comprise a third trace 183, may be located between dielectric layer 166 and second waveguide layer 168.

First waveguide layer 163 may comprise a first cladding 186 encapsulating a first plurality of waveguides 189. A material comprising first cladding 186 may have a different refractive index than a material comprising any of first plurality of waveguides 189. Second waveguide layer 168 may comprise a second cladding 192 encapsulating a second plurality of waveguides 195. A material comprising second cladding 192 may have a different refractive index than a material comprising any of second plurality of waveguides 195. The difference in refractive index may tend to cause light traveling in first plurality of waveguides 189 or second plurality of waveguides 195 to stay in the waveguides and not dissipate into first cladding 186 or second cladding 192 respectively.

Consistent with embodiments of the disclosure, waveguide layers (e.g., first waveguide layer 163 and second waveguide layer 168) may serve simultaneously as layers for providing optical waveguides (e.g., first plurality of waveguides 189 and second plurality of waveguides 195) and as a dielectric between signal layers (e.g., the first signal layer and the second signal layer) and a reference plane (e.g., first plane layer 171 and the second plane layer 174). For example, first waveguide layer 163 and second waveguide layer 168 may have at least the same dielectric qualities as the prior art dielectric layers (i.e., first dielectric layer 103 and third dielectric layer 109). Consistent with embodiments of the disclosure, dielectric layer 166 may be replaced with a layer similar to first waveguide layer 163 or second waveguide layer 168.

FIG. 1C shows a PCB 198 consistent with embodiments of the disclosure. As shown in FIG. 1C, PCB 198 may comprise a combination of any one or more of PCB 127 and PCB 160. For example, PCB 198 may comprise a combination of two PCBs each comprising PCB 127, PCB 160, or a combination of the two.

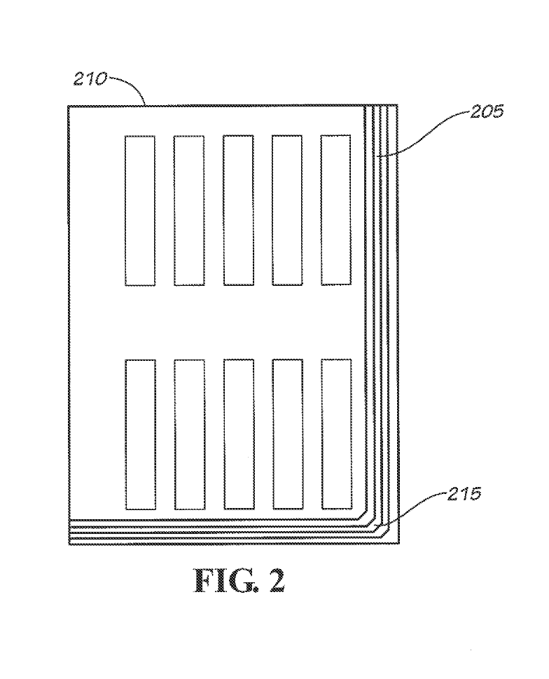

FIG. 2 is a top-down view, consistent with embodiments of the disclosure, illustrating routing of a plurality of waveguides 205 within a representative backplane PCB 210. As shown in FIG. 2, a 90° turn in the light path may be effected by one or more 45° reflective mirrors 215 within any one or more of plurality of waveguides 205. Plurality of waveguides 205 may comprise, but are not limited to, any of the plurality of waveguides described above with respect to FIG. 1A, FIG. 1B, and FIG. 1C.

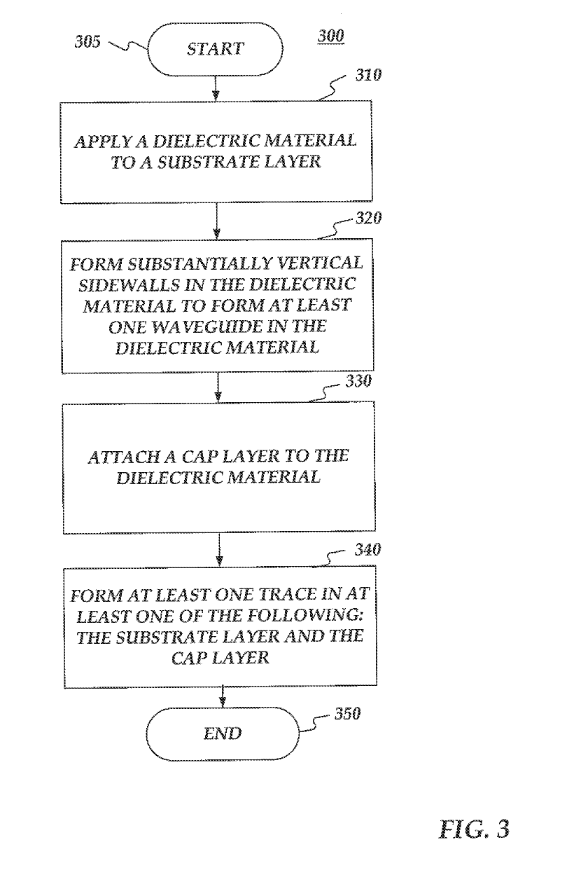

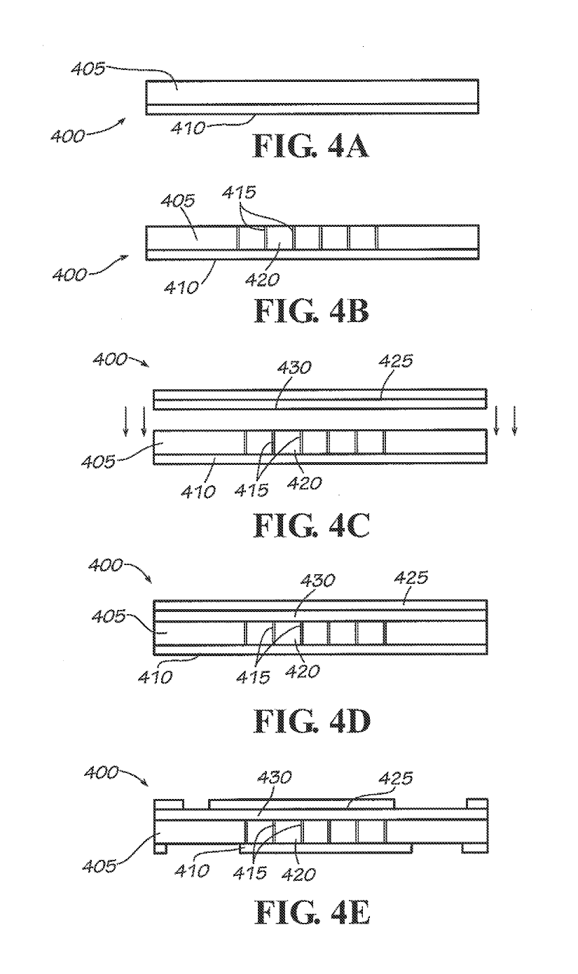

FIG. 3 is a flow chart setting forth the general stages involved in a method 300 consistent with an embodiment of the disclosure for providing a combined waveguide/dielectric layer of a PCB 400 using photo-defined sidewalls as shown in FIGS. 4A through 4E. Method 300 may be implemented using PCB manufacturing processes. Ways to implement the stages of method 300 will be described in greater detail below.

Method 300 may begin at starting block 305 and proceed to stage 310 where a dielectric material 405 may be applied to a substrate layer 410 as shown in FIG. 4A. For example, substrate layer 410 may be a metallic foil sheet and may comprise, but is not limited to, copper, tin, nickel, gold, and silver. Dielectric material 405 may comprise an optically transparent polymeric plastic comprising, but not limited to, cyclic-olefin polymer, polycarbonate, polymethyl methacrylate, epoxy, acrylate, or blended combination thereof. Dielectric material 405 may be applied to substrate layer 410 in a film or liquid form. Furthermore, dielectric material 405 may be doped with one or more additives for the purpose of altering the Dielectric Constant (Dk) or Dissipation Factor (Df) of dielectric material 405 to achieve a desired Dk and/or Df.

From stage 310, where dielectric material 405 is applied to substrate layer 410, method 300 may advance to stage 320 where substantially vertical/horizontal sidewalls 415 may be formed in dielectric material 405 to form at least one waveguide 420 in dielectric material 405 as shown in FIG. 4B. For example, coherent direct-energy beams may be used to form substantially vertical/horizontal sidewalls 415 in dielectric material 405. Specifically, dielectric material 405 may be exposed to a directed-energy beam that alters the refractive index of dielectric material 405 thus creating substantially vertical/horizontal sidewalls 415 causing an internally-reflective pattern in dielectric material 405 between substantially vertical/horizontal sidewalls 415 to form at least one waveguide 420. At least one waveguide 420 may comprise original, unreacted material. The difference in refractive index between at least one waveguide 420 and substantially vertical/horizontal sidewalls 415 may tend to cause light traveling in at least one waveguide 420 to stay in the waveguide and not dissipate into substantially vertical/horizontal sidewalls 415.

To facilitate the coherent direct-energy beams in creating substantially vertical/horizontal sidewalls 415, dielectric material 405 may be doped with at least one photo-sensitizing agent for the purpose of enabling formation of the desired waveguide structures through photo-polymerization (i.e., crosslinking). Moreover, dielectric material 405 may be doped with at least one sensitizing agent for the purpose of enabling the refractive index of dielectric material 405 to be altered by exposure to one or more types of photonic radiation comprising, but not limited to, radio-frequency radiation, microwave radiation, infra-red light, visible light, ultraviolet light, and x-rays. In addition, dielectric material 405 may be doped with at least one sensitizing agent for the purpose of enabling the refractive index of dielectric material 405 to be altered by exposure to one or more types of particle radiation, comprising, but not limited to, beta particles (electrons), alpha particles, positrons or neutrons.

Once substantially vertical/horizontal sidewalls 415 are formed in stage 320, method 300 may continue to stage 330 where a cap layer 425 may be attached to dielectric material 405 as shown in FIG. 4C and FIG. 4D. For example, cap layer 425 may comprise a sheet of metallic foil coated on one side with a primer or an adhesive 430. Cap layer 425 may be a metallic foil sheet and may comprise, but is not limited to, copper, tin, nickel, gold, and silver. Cap layer 425 may then be laminated upon dielectric material 405 thus forming, for example, a metal-clad sandwich as shown in FIG. 4D.

After cap layer 425 is attached to dielectric material 405 in stage 330, method 300 may proceed to stage 340 where at least one trace may be formed in substrate layer 410 and cap layer 425 as shown in FIG. 4E. For example, the laminated structure shown in FIG. 4D may then be imaged and etched to form circuit patterns in substrate layer 410 and cap layer 425, resulting in a complete PCB. Consistent with embodiments of the disclosure, dielectric material 405 may serve the function of a dielectric between cap layer 425 and substrate layer 410. In addition, dielectric material 405 may serve as a waveguide layer.

Consistent with embodiments of the disclosure, PCB 400 may comprise a combination of waveguide layer 133, first signal layer, and second signal layer as described above with respect to FIG. 1A. If substrate layer 410 or cap layer 425 is not etched, PCB 400 may comprise a combination of first waveguide layer 160, first plane layer 171, first signal layer as described above with respect to FIG. 1B. Similarly, PCB 400 may comprise a combination of second waveguide layer 168, second plane layer 174, and second signal layer as described above with respect to FIG. 1B. Once at least one trace is formed in stage 340, method 300 may then end at stage 350.

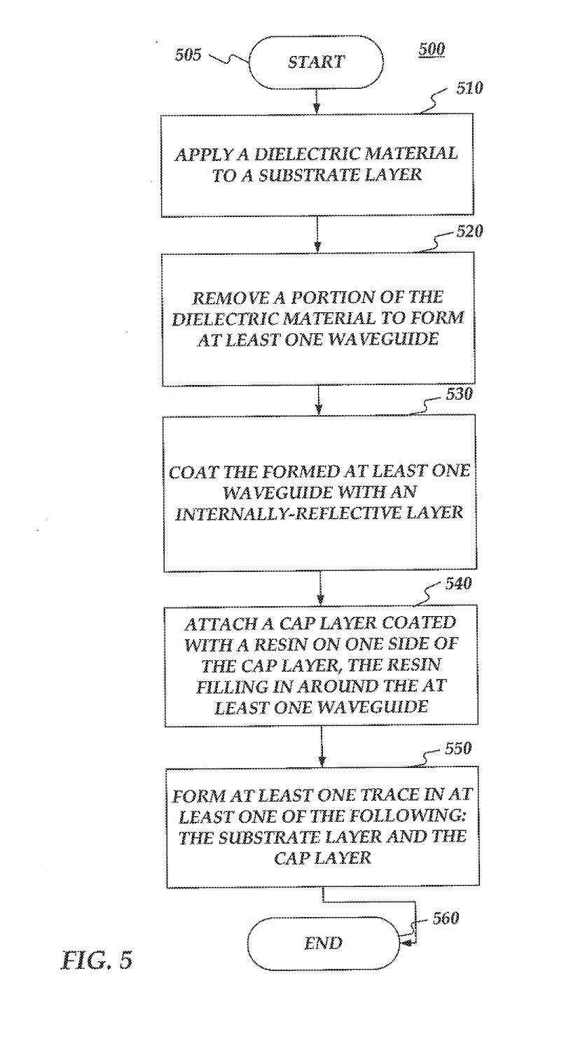

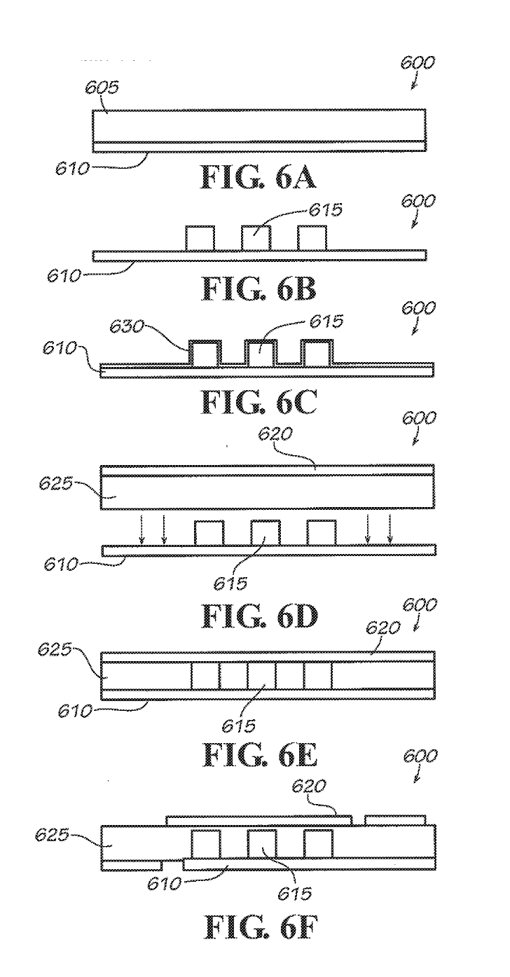

FIG. 5 is a flow chart setting forth the general stages involved in a method 500 consistent with an embodiment of the disclosure for providing a combined waveguide/dielectric layer of a PCB 600 using an ablative process as shown in FIGS. 6A through 6F. Method 500 may be implemented using PCB manufacturing processes. Ways to implement the stages of method 500 will be described in greater detail below.

Method 500 may begin at starting block 505 and proceed to stage 510 where a dielectric material 605 may be applied to a substrate layer 610 as shown in FIG. 4A. For example, substrate layer 610 may be a metallic foil sheet and may comprise, but is not limited to, copper, tin, nickel, gold, and silver. Dielectric material 605 may comprise an optically transparent polymeric plastic comprising, but not limited to, cyclic-olefin polymer, polycarbonate, polymethyl methacrylate, epoxy, acrylate, or blended combination thereof. Dielectric material 605 may be applied to substrate layer 610 in a film or liquid form. Furthermore, dielectric material 605 may be doped with one or more additives for the purpose of altering the Dielectric Constant (Dk) or Dissipation Factor (Df) dielectric material 605 to achieve a desired Dk and/or Df.

From stage 510, where dielectric material 605 is applied to substrate layer 610, method 500 may advance to stage 520 where a portion of dielectric material 605 may be removed to form at least one waveguide 615 as shown in FIG. 6B. At least one waveguide 615 may be formed by ablation of unwanted material in dielectric material 605. For example, such ablation may be accomplished by any suitable process, such as but not limited to, photo-developing, laser cutting, ultrasonic energy, chemical milling, water-jet cutting, vapor honing, or mechanical milling by cutting tools. Dielectric material 605 may be doped with one or more additives that alter the modulus of dielectric material 605 for the purpose of increasing fracture resistance during mechanical ablation, such as but not limited to, mechanical milling or laser-jet cutting.

Once the portion of the dielectric material is removed in stage 520, method 500 may continue to stage 530 where formed at least one waveguide 615 may be coated with an internally-reflective layer 630 to improve the internal reflectivity of at least one waveguide 615 as shown in FIG. 6C. For example, in cases where the refractive index of at least one waveguide 615 is excessively similar to that of any surrounding material (e.g., a resin 625 described below) that it is laminated to and in direct contact with, an internally-reflective layer 630 may be added to improve the internal reflectivity of the at least one waveguide 615. A condition for proper functioning of an optical waveguide is that surrounding material be of a sufficiently different refractive index. In cases where the refractive indices of the two materials are excessively close, an optical insulating layer (e.g., internally-reflective layer 630) of sufficiently different refractive index may be applied to the external surfaces of the waveguide layer.

Consistent with embodiments of the disclosure, internally-reflective layer 630 may comprise a thin coating of organic material applied to the external surfaces of at least one waveguide 615 by any suitable process such as dipping, spraying, chemical vapor deposition or roller coating. Internally-reflective layer 630 may comprise a thin metallic coating, of any suitable metal, applied by any suitable process such as immersion or electroless chemical deposition, chemical vapor deposition, vacuum deposition, or plasma-enhanced vacuum deposition.

After forming at least one waveguide 615 is coated in stage 530, method 500 may proceed to stage 540 where a cap layer 620 coated with resin 625 on one side may be attached as shown in FIGS. 6D and 6E. Cap layer 620 may comprise a metallic foil sheet that may comprise, but is not limited to, copper, tin, nickel, gold, and silver. Resin 625 may fill in around at least one waveguide 615. For example, cap layer 620 may comprise a sheet of metallic foil coated on one side with a primer or adhesive (e.g., resin 625). Cap layer 620 may be laminated upon dielectric material 605, forming a metal-clad sandwich as resin 625 flows around and encapsulates the discrete waveguide structures (e.g., at least one waveguide 615).

From stage 540, where the cap layer coated with the resin is attached, method 500 may advance to stage 550 where at least one trace may be formed in the substrate layer 610 and/or the cap layer 620. For example, the laminated structure shown in FIG. 6E may then be imaged and etched to form circuit patterns in substrate layer 610 and cap layer 620, resulting in a complete PCB. Consistent with embodiments of the disclosure, dielectric material 605 can serve the function of a dielectric between cap layer 620 and substrate layer 610. In addition, dielectric material 605 can serve as a waveguide layer. The difference in refractive index between at least one waveguide 615 and resin 625 may tend to cause light traveling in at least one waveguide 615 to stay in the waveguide and not dissipate into resin 625. Also, internally-reflective layer 630 may tend to cause light traveling in at least one waveguide 615 to stay in the waveguide and not dissipate into resin 625.

Consistent with embodiments of the disclosure, PCB 600 may comprise a combination of waveguide layer 133, first signal layer, and second signal layer as described above with respect to FIG. 1A. If substrate layer 610 or cap layer 620 is not etched, PCB 600 may comprise a combination of first waveguide layer 160, first plane layer 171, and first signal layer as described above with respect to FIG. 1B. Similarly, PCB 600 may comprise a combination of second waveguide layer 168, second plane layer 174, and second signal layer as described above with respect to FIG. 1B. Once the at least one trace is formed in stage 550, method 500 may then end at stage 560.

An embodiment consistent with the disclosure may comprise a method for providing a combined waveguide/dielectric layer of a PCB using photo-defined sidewalls. The method may comprise applying a dielectric material to a substrate layer and forming substantially vertical/horizontal sidewalls in the dielectric material to form at least one waveguide in the dielectric material. The method may further comprise attaching a cap layer to the dielectric material and forming at least one trace in at least one of the following: the substrate layer and the cap layer.

Another embodiment consistent with the disclosure may comprise a method for providing a combined waveguide/dielectric layer of a PCB using an ablative process. The method may comprise applying a dielectric material to a substrate layer and removing a portion of the dielectric material to form at least one waveguide. The method may further comprise attaching a cap layer coated with a resin on one side of the cap layer (the resin filling in around the at least one waveguide) and forming at least one trace in at least one of the following: the substrate layer and the cap layer.

Yet another embodiment consistent with the disclosure may comprise an apparatus that provides a combined waveguide/dielectric layer of a PCB. The apparatus may comprise a first electrically conductive layer comprising a first signal layer and a second electrically conductive layer comprising one of the following: a second signal layer and a plane layer. The apparatus may further comprise a waveguide layer disposed adjacent the first electrically conductive layer and adjacent the second electrically conductive layer.

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A method comprising:
applying a dielectric material to a substrate layer;
forming substantially vertical sidewalls in the dielectric material to form at least one waveguide in the dielectric material;
attaching a cap layer to the dielectric material; and
forming at least one trace in at least one of the following: the substrate layer and the cap layer.

2. The method of claim 1, wherein applying the dielectric material to the substrate layer comprises applying the dielectric material to the substrate layer comprising a foil sheet.

3. The method of claim 1, wherein applying the dielectric material to the substrate layer comprises applying the dielectric material to the substrate layer comprising a foil sheet comprising one of the following: copper, tin, nickel, gold, and silver.

4. The method of claim 1, wherein applying the dielectric material to the substrate layer comprises applying the dielectric material in a film form.

5. The method of claim 1, wherein applying the dielectric material to the substrate layer comprises applying the dielectric material in a liquid form.

6. The method of claim 1, wherein forming the substantially vertical sidewalls in the dielectric material comprises causing a portion of the dielectric material comprising the substantially vertical sidewalls to have a refractive index different from the formed at least one waveguide.

7. The method of claim 1, wherein forming the substantially vertical sidewalls in the dielectric material comprises using a coherent directed-energy beam.

8. The method of claim 1, wherein attaching the cap layer to the dielectric material comprises attaching the cap layer comprising a foil coated on one side with an adhesive, the foil sheet comprising one of the following: copper, tin, nickel, gold, and silver.

9. The method of claim 1, wherein forming the at least one trace comprises patterning and etching the at least one of the following: the substrate layer and the cap layer.

10. A method comprising:
applying a dielectric material to a substrate layer;
removing a portion of the dielectric material to form at least one waveguide;
attaching a cap layer coated with a resin on one side of the cap layer, the resin filling in around the at least one waveguide; and
forming at least one trace in at least one of the following: the substrate layer and the cap layer.

11. The method of claim 10, wherein applying the dielectric material to the substrate layer comprises applying the dielectric material to the substrate layer comprising a foil sheet.

12. The method of claim 10, wherein applying the dielectric material to the substrate layer comprises applying the dielectric material to the substrate layer comprising a foil sheet comprising one of the following: copper, tin, nickel, gold, and silver.

13. The method of claim 10, wherein applying the dielectric material to the substrate layer comprises applying the dielectric material in a film form.

14. The method of claim 10, wherein applying the dielectric material to the substrate layer comprises applying the dielectric material in a liquid form.

15. The method of claim 10, wherein removing the portion of the dielectric material comprises using photo-imaging.

16. The method of claim 10, wherein removing the portion of the dielectric material comprises using ablation.

17. The method of claim 10, wherein attaching the cap layer comprises attaching the cap layer comprising a foil sheet comprising one of the following: copper, tin, nickel, gold, and silver.

18. The method of claim 10, wherein attaching the cap layer coated with the resin comprises attaching the cap layer coated with the resin comprising an adhesive.

19. The method of claim 10, wherein forming the at least one trace comprises patterning and etching the at least one of the following: the substrate layer and the cap layer.

20. The method of claim 10, further comprising coating the formed at least one waveguide with an internally-reflective layer.

21. The method of claim 20, wherein coating the formed at least one waveguide with the internally-reflective layer comprises coating the formed at least one waveguide with the internally-reflective layer comprising a metallic material.

22. The method of claim 20, wherein coating the formed at least one waveguide with the internally-reflective layer comprises coating the formed at least one waveguide with the internally-reflective layer comprising an organic material.

23. An apparatus comprising:
a first electrically conductive layer comprising a first signal layer;
a second electrically conductive layer comprising one of the following: a second signal layer and a plane layer; and
a waveguide layer disposed adjacent the first electrically conductive layer and adjacent the second electrically conductive layer.

24. The apparatus of claim 23, wherein the first electrically conductive layer comprises at least one trace.

25. The apparatus of claim 23, wherein the waveguide layer may comprise at least one waveguide.

26. The apparatus of claim 25, wherein the waveguide layer comprises a cladding encapsulating the at least one waveguide.

27. The apparatus of claim 26, wherein the at least one waveguide and the cladding have different refractive indexes.

28. The apparatus of claim 23, wherein the waveguide layer is configured to provide a dielectric between the first electrically conductive layer and the second electrically conductive layer.
